(19) United States
(12) Patent Application Publication
(10) Pub. No.: US 2023/0187185 A1
(43) Pub. Date: Jun. 15, 2023

(54) PLASMA BAFFLE, SUBSTRATE PROCESSING APPARATUS INCLUDING THE SAME, AND SUBSTRATE PROCESSING METHOD USING THE SAME

(71) Applicant: SAMSUNG ELECTRONICS CO., LTD., Suwon-si (KR)

(72) Inventors: SUMIN PARK, Yongin-si (KR); SUNGHWAN KIM, Hanam-si (KR); HAKYOUNG KIM, Bucheon-si (KR); DAEHYUN LEE, Suwon-si (KR); DONGYUN YEO, Seoul (KR); MINYOUNG HUR, Hwaseong-si (KR)

(73) Assignee: SAMSUNG ELECTRONICS CO., LTD., Suwon-si (KR)

(21) Appl. No.: 17/948,943

(22) Filed: Sep. 20, 2022

(30) Foreign Application Priority Data
Dec. 13, 2021 (KR) 10-2021-0178023

(51) Int. Cl. H01J 37/32

(52) U.S. Cl. CPC H01J 37/32633; H01J 37/3244; H01J 37/32834; H01J 37/32082; H01J 2237/327

(57) ABSTRACT

A plasma battle includes a lower ring and an upper ring that extends upwardly from an edge of the lower ring. The lower ring includes a lower central hole on a center of the lower ring and vertically penetrating the lower ring and a lower slit outside the lower central hole and vertically penetrating the lower ring. The upper ring includes an upper central hole on a center of the upper ring and vertically penetrating the upper ring and an upper slit that penetrates the upper ring so as to connect an inner lateral surface of the upper ring to an outer lateral surface of the upper ring.

### CROSS-REFERENCE TO RELATED APPLICATION

This application is based on and claims priority under 35 U.S.C § 119 to Korean Patent Application No. 10-2021-0178023, filed on Dec. 13, 2021 in the Korean Intellectual Property Office, the disclosure of which is incorporated by reference herein in its entirety.

### BACKGROUND

The present disclosure relate to a plasma baffle, a substrate processing apparatus including the same, and a substrate processing method using the same, and more particularly, to a plasma baffle capable of improving plasma distribution, a substrate processing apparatus including the same, and a substrate processing method using the same.

A semiconductor device may be fabricated through various processes. For example, the semiconductor device may be manufactured by photolithography process, an etching process, and a deposition process performed on a silicon wafer. Various fluids may be used in such processes. For example, plasma may be used in an etching process and/or a deposition process. It may be required to control a position of plasma during processes. A plasma baffle may be utilized to control plasma distribution and to discharge vapors.

### SUMMARY

Some embodiments of the present disclosure provide a plasma baffle capable of improving a deviation in plasma on a substrate edge region, a substrate processing apparatus including the same, and a substrate processing method using the same.

Some embodiments of the present disclosure provide a plasma baffle capable of diversifying parameters to control plasma distribution in various ways, a substrate processing apparatus including the same, and a substrate processing method using the same.

Some embodiments of the present disclosure provide a plasma baffle capable of controlling plasma distribution in a circumferential direction, a substrate processing apparatus including the same, and a substrate processing method using the same.

Additional aspects will be set forth in part in the description which follows and, in part, will be apparent from the description, or may be learned by practice of the presented embodiments.

According to an aspect of an example embodiment, a plasma battle may include a lower ring and an upper ring that extends upwardly from an edge of the lower ring. The lower ring may include a lower central hole on a center of the lower ring and vertically penetrating the lower ring and a lower slit outside the lower central hole and vertically penetrating the lower ring. The upper ring may include an upper central hole on a center of the upper ring and vertically penetrating the upper ring and an upper slit that penetrates the upper ring so as to connect an inner lateral surface of the upper ring to an outer lateral surface of the upper ring.

According to an aspect of an example embodiment, a substrate processing apparatus may include a stage configured to support a substrate and a plasma baffle that surrounds the stage. The plasma baffle may include a lower ring including a lower central hole. The lower ring may include a lower slit that extends in a radial direction and vertically penetrates the lower ring. The lower slit may include a first lower slit and a second lower slit space apart in a circumferential direction from the first lower slit. A length of the first lower slit in a radial direction of the first lower slit in the radial direction may be different from a length of the second lower slit in the radial direction.

According to an aspect of an example embodiment, a substrate processing method may include providing a substrate on a stage of a substrate processing apparatus, supplying a process gas to a process chamber of the substrate processing apparatus, exhausting a portion of the process gas from the process chamber, and applying a radio-frequency (RF) power to generate plasma on the substrate. The substrate processing apparatus may include a plasma baffle that surrounds the stage. The plasma baffle may include a lower ring and an upper ring that extends upwardly from an edge of the lower ring. The lower ring may include a lower slit that extends in a radial direction and vertically penetrates the lower ring. The upper ring may include an upper slit that penetrates the upper ring so as to connect an inner lateral surface of the upper ring to an outer lateral surface of the upper ring. Exhausting the portion of the process gas from the process chamber may include allowing the portion of the process gas to pass through the upper slit.

Details of other example embodiments are included in the description and drawings.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a cross-sectional view of a substrate processing apparatus according to an example embodiment;

FIG. 2 is a perspective view of a plasma baffle according to an example embodiment;

FIG. 3 is an enlarged cutaway perspective view of a plasma baffle according to an example embodiment;

FIG. 4 is a cross-sectional view of a plasma baffle according to an example

embodiment;

FIG. 5 is a cross-sectional view partially of a plasma baffle according to an example embodiment;

FIG. 6 is a plan view of a plasma baffle according to an example embodiment; FIG. 7 is a flowchart of a substrate processing method according to an example embodiment;

FIGS. 8, 9, 10 and 11 are cross-sectional views of a substrate processing method according to the flowchart of FIG. 7, according to an example embodiment;

FIG. 12 is a plan view of a plasma baffle according to an example embodiment;

FIG. 13 is a plan view of a plasma baffle according to an example embodiment;

FIG. 14 is an enlarged cutaway perspective view of a plasma baffle according to an example embodiment;

FIG. 15 is an enlarged cutaway perspective view partially of a plasma baffle according to an example embodiment; and

FIG. 16 is an enlarged cutaway perspective view partially of a plasma baffle according to an example embodiment.

### DETAILED DESCRIPTION

Example embodiments of the present disclosure will be described with reference to the accompanying drawings. Like reference numerals may indicate like components throughout the description.

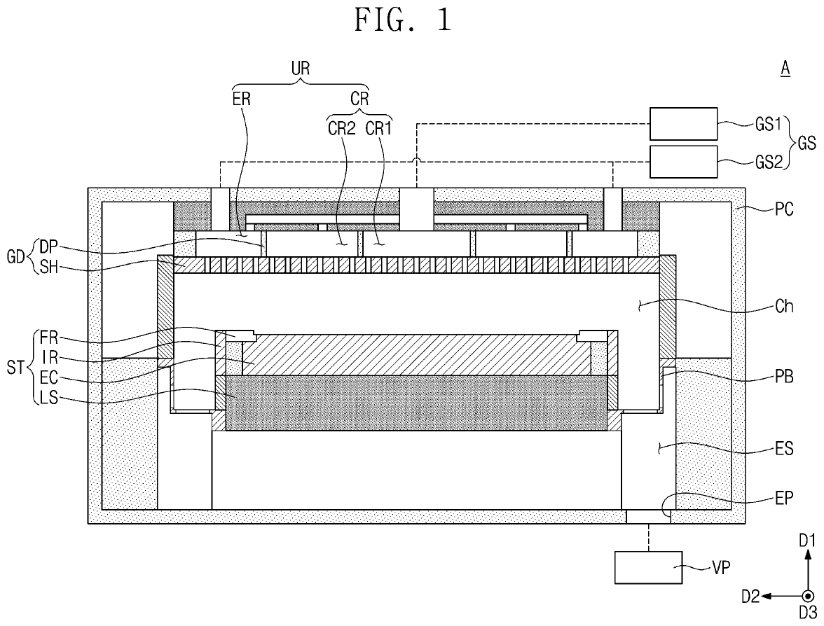

FIG. 1 is a cross-sectional view of a substrate processing apparatus according to an example embodiment.

In this description, symbol D1 may indicate a first direction, symbol D2 may indicate a second direction that intersects the first direction D1, and symbol D3 may indicate a third direction that intersects each of the first and second directions D1 and D2.

Referring to FIG. 1, a substrate processing apparatus A may be provided. The substrate processing apparatus A may refer to a device that uses plasma to process a substrate. A substrate may include a silicon wafer, but the present disclosure are not limited thereto. The substrate processing apparatus A may be configured such that the plasma is used to perform an etching process and/or a deposition process on a substrate. The substrate processing apparatus A may use various ways to generate the plasma. For example, the substrate processing apparatus A may generate the plasma by using a capacitively coupled plasma (CCP) mode, an inductively coupled plasma (ICP) mode, or a magnetically enhanced reactive ion etching (MERIE) mode. The present disclosure, however, is not limited thereto, and the substrate processing apparatus A may use other ways to generate the plasma so as to perform a process on the substrate. For convenience, the following will describe the substrate process apparatus A operated in the CCP mode.

The substrate processing apparatus A may include a process chamber PC, a gas supply unit GS, a gas distribution unit GD, a stage ST, a plasma baffle PB, and a vacuum pump VP.

The process chamber PC may provide a process space Ch. The process chamber PC may be connected to the gas supply unit GS to receive a process gas from the gas supply unit GS. The process chamber PC may be connected to the vacuum pump VP. A fluid, such as a process gas, in the process space Ch may be introduced into the vacuum pump VP. The process chamber PC may provide an exhaust port EP. The process space Ch may be connected through the exhaust port EP to the vacuum pump VP. The exhaust port EP may be positioned biased towards one side in the process chamber PC. For example, the exhaust port EP may be positioned biased towards a right-side based on FIG. 1. A detailed description thereof will be further discussed below. The stage ST and the plasma baffle PB may be disposed in the process chamber PC.

The gas supply unit GS may supply a process gas into the process space Ch. The gas supply unit GS may include a gas tank, a compressor, a pipe line, a controller, and so forth. The gas supply unit GS may supply many kinds of gas. The gas supply unit GS may include a first gas supply unit GS1 and a second gas supply unit GS2. The first gas supply unit GS1 may supply a first process gas. The process space Ch may be supplied and completely filled with the first process gas. The second gas supply unit GS2 may supply a second process gas. The second process gas may include a gas whose kind is distinguished from that of the first process gas. The second process gas may be supplied to be biased towards one side in the process space Ch. A detailed description thereof will be further discussed below.

The gas distribution unit GD may be positioned in the process chamber PC. The gas distribution unit GD may distribute a process gas over the process space Ch. The gas distribution unit GD may include a showerhead SH and a gas separation plate DP. The showerhead SH may provide a plurality of gas supply holes. The showerhead SH may serve as a top electrode. The showerhead SH may divide a distribution space UR and the process space Ch from each other, and the distribution space UR may be a space above the showerhead SH. The distribution space UR may be divided into a central region CR and an edge region ER. For example, the gas separation plate DP may divide the central region CR and the edge region ER from each other. The central region CR may be separated into a first central region CR1 and a second central region CR2. The first process gas may be supplied to all of the first central region CR1, the second central region CR2, and the edge region ER. The second process gas may be supplied only to the edge region ER. A process gas supplied in the distribution space UR may move to the process space Ch after being distributed through the gas supply holes of the showerhead SH.

The stage ST may support a substrate. The stage ST may be positioned in the process chamber PC. The stage ST may include an electrostatic chuck EC, a lower supporter LS, a focus ring FR, and an insulating ring IR.

The electrostatic chuck EC may support a substrate. The electrostatic chuck EC may use an electrostatic force to fix a substrate to a certain position. The electrostatic chuck EC may include a chuck electrode. In addition, the electrostatic chuck EC may be provided therein with a heater and/or a cooling passage. Moreover, the electrostatic chuck EC may be provided therein with a plasma electrode to which a radio-frequency (RF) power is applied. Alternatively, the plasma electrode may be positioned beneath the electrostatic chuck EC. The lower supporter LS may support the electrostatic chuck EC. The focus ring FR may surround the electrostatic chuck EC. For example, when viewed in plan, the focus ring FR may surround a substrate disposed on the electrostatic chuck EC. The insulating ring IR may surround the focus ring FR.

The plasma baffle PB may surround the stage ST. For example, beneath the electrostatic chuck EC, the plasma baffle PB may surround the stage ST. The present disclosure, however, is not limited thereto, and at a height similar to that of the focus ring FR, the plasma baffle PB may surround the stage ST. Alternatively, the plasma baffle PB may be located at a position higher than that of the focus ring FR. A space under the plasma baffle PB may be referred to as an exhaust space ES. The exhaust space ES may be connected to the exhaust port EP. The plasma baffle PB may allow a gas to pass from the process space Ch to the exhaust space ES. For example, a gas in the process space Ch may pass through the plasma baffle PB to the exhaust space ES, thereby being discharged from the exhaust port EP. The plasma may not be allowed to easily pass through the plasma baffle PB. For example, the plasma baffle PB may limit a position of the plasma. The plasma baffle PB may allow the plasma to concentrate on a substrate disposed on the stage ST. Therefore, the plasma baffle PB may be referred to as a confinement ring. The plasma baffle PB may be fixed to the stage ST and/or the process chamber PC. For example, the plasma baffle PB may be fixed to the process chamber PC through a bolt or the like. The plasma baffle PB will be further discussed in detail below.

The vacuum pump VP may be connected to the process chamber PC. For example, the vacuum pump VP may be connected through the exhaust port EP to the process space Ch. The vacuum pump VP may draw a fluid from the process space Ch. The vacuum pump VP may be positioned on one side below the process chamber PC. The present disclosure, however, is not limited thereto, and the vacuum pump VP may be positioned on a lateral side of the process chamber PC.

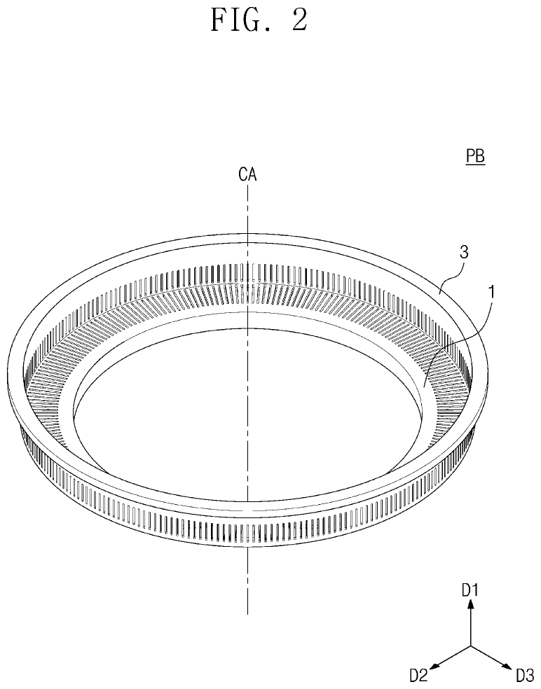

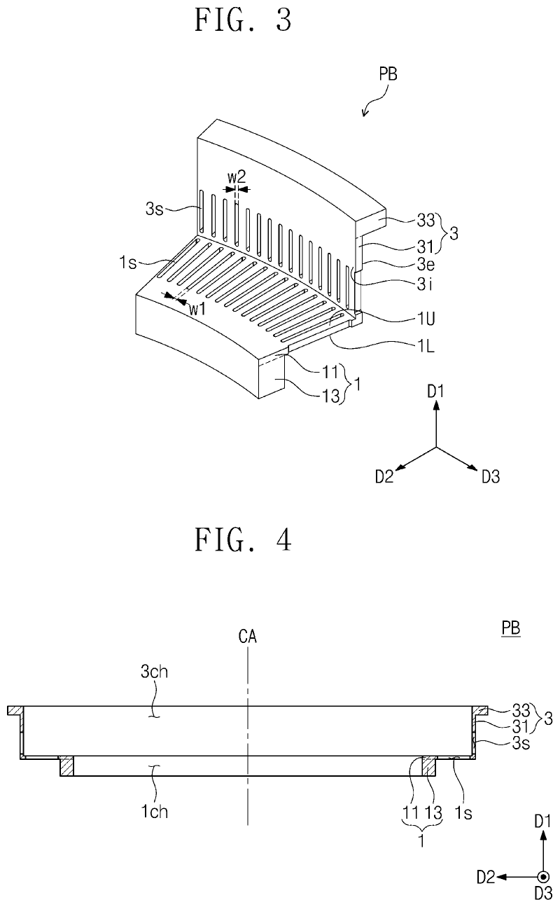

FIG. 2 is a perspective view of a plasma baffle according to an example embodiment. FIG. 3 is an enlarged cutaway perspective view of a plasma baffle according to an example embodiment. FIG. 4 is a cross-sectional view of a plasma baffle according to an example embodiment.

Referring to FIGS. 2, 3, and 4, the plasma baffle PB may have a ring shape around a central axis CA. The plasma baffle PB may include a lower ring 1 and an upper ring 3.

The lower ring 1 may provide a lower central hole 1ch and a lower slit 1s.

The lower central hole 1ch may vertically penetrate the lower ring 1. The lower central hole 1ch may pass through a center of the lower ring 1. For example, the central axis CA may penetrate the lower central hole 1ch.

The lower slit 1s may be positioned outside the lower central hole 1ch. The lower slit 1s may vertically penetrate the lower ring 1. For example, the lower slit 1s may penetrate the lower ring 1 to connect a top surface 1U of the lower ring 1 to a bottom surface 1L of the lower ring 1. The lower slit 1s may extend a certain length in a radial direction. A lower slit width w1 may be defined to indicate a width of the lower slit 1s. The lower slit width w1 may refer to a length in a circumferential direction of the lower slit 1s. The lower slit width w1 may range from about 1.0 mm to about 5 mm, but the present disclosure are not limited thereto. The lower slit 1s may include a plurality of lower slits. The plurality of lower slits 1s may be spaced apart from each other in a circumferential direction. In this description, a single lower slit 1s is discussed unless otherwise noted.

The lower ring 1 may include a lower body 11 and a lower extension member 13. The lower body 11 may have a disk shape. The lower slit 1s may be provided on the lower body 11. For example, the lower slit 1s may vertically penetrate the lower body 11. The lower extension member 13 may be downwardly connected to the lower body 11. The lower extension member 13 may define a portion of the lower central hole 1ch. The lower extension member 13 may be coupled to another component such as the stage (see ST of FIG. 1). The lower extension member 13 and the lower body 11 may be formed integrally into a single unitary piece, but the present disclosure are not limited thereto.

The upper ring 3 may be disposed on the lower ring 1. The upper ring 3 may extend upwardly from an edge of the lower ring 1. For example, an angle of about 90° may be formed between the upper ring 3 and the lower ring 1. For example, the upper ring 3 may vertically extend upwards from the edge of the lower ring 1. The present disclosure, however, is not limited thereto, and the upper ring 3 and the lower ring 1 may form an acute angle or an obtuse angle therebetween. The upper ring 3 may provide an upper central hole 3ch and an upper slit 3s.

The upper central hole 3ch may vertically penetrate the upper ring 3. The upper central hole 3ch may pass through a center of the upper ring 3. For example, the central axis CA may penetrate the upper central hole 3ch. The upper central hole 3ch may be spatially connected to the lower central hole 1ch.

The upper slit 3s may be positioned outside the upper central hole 3ch. The upper slit 3s may penetrate the upper ring 3 so as to connect an inner lateral surface 3i of the upper ring 3 to an outer lateral surface 3e of the upper ring 3. For example, the upper slit 3s may extend in a radial direction to penetrate the upper ring 3. The upper slit 3s may vertically extend a certain length. An upper slit width w2 may be defined to indicate a width of the upper slit 3s. The upper slit width w2 may refer to a length in a circumferential direction of the upper slit 3s. The upper slit width w2 may be substantially the same as or similar to the lower slit width w1. For example, the upper slit width w2 may range from about 1.0 mm to about 5 mm, but the present disclosure are not limited thereto. The upper slit 3s may be an aperture independently present separated from the lower slit 1s. The upper slit 3s may not be spatially connected to the lower slit 1s. For example, the upper slit 3s may be spaced apart from the lower slit 1s. For more detail, the upper slit 3s may be upwardly spaced apart from the lower slit 1s. The upper slit 3s may be provided in plural. The plurality of upper slits 3s may be spaced apart from each other in a circumferential direction. In this description, a single upper slit 3s is discussed unless otherwise noted.

The upper ring 3 may include an upper body 31 and an upper extension member 33. The upper slit 3s may be provided on the upper body 31. For example, the upper slit 3s may penetrate in a radial direction through the upper body 31. The upper extension member 33 may be upwardly connected to the upper body 31. The upper extension member 33 may be coupled to another component such as the process chamber (see PC of FIG. 1). The upper extension member 33 and the upper body 31 may be integrally connected into a single unitary piece, but the present disclosure is not limited thereto.

It is explained that the plasma baffle PB includes the lower ring 1 and the upper ring 3, but the present disclosure is not limited thereto. For example, the plasma baffle PB may have a shape in which only the lower ring 1 is present without the upper ring 3. Alternatively, the plasma baffle PB may include another ring on the upper ring 3. Such rings may be integrally connected into a single unitary piece or may be detachably coupled to each other. Such rings may include one or more of aluminum (Al) and yttrium oxide (Y₂O₃), but the present disclosure are not limited thereto.

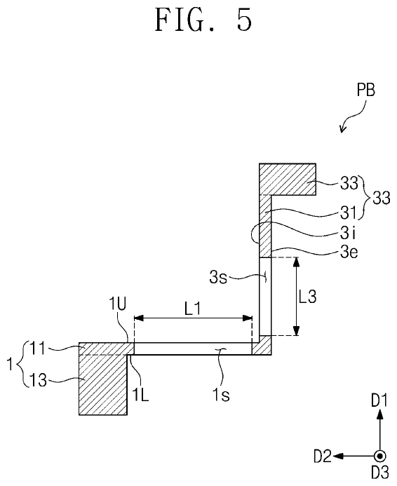

FIG. 5 is a cross-sectional view partially of a plasma baffle according to an example embodiment.

Referring to FIG. 5, a length of the lower slit 1s may be referred to as a lower slit length L1. The lower slit length L1 may indicate a length in a radial direction. The lower slit length L1 may range from about 70 mm to about 100 mm. For example, the lower slit length L1 may be about 80 mm. The present disclosure, however, is not limited thereto.

A length of the upper slit 3s may be referred to as an upper slit length L3. The upper slit length L3 may indicate a length of the upper slit 3s in an extending direction of the upper ring 3. The upper slit length L3 may be less than lower slit length L1. The upper slit length L3 may range from about 30 mm to about 50 mm. For example, the upper slit length L3 may be about 40 mm. The present disclosure, however, is not limited thereto, and the upper slit length L3 may be greater than the lower slit length L1.

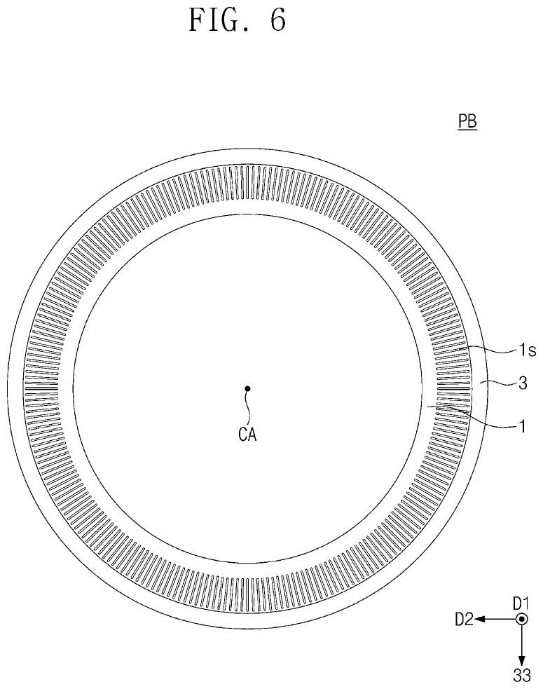

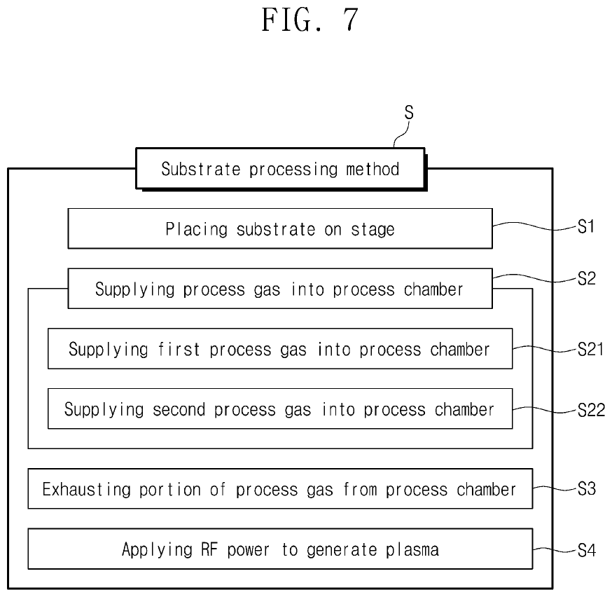

FIG. 6 is a plan view of a plasma baffle according to an example embodiment.

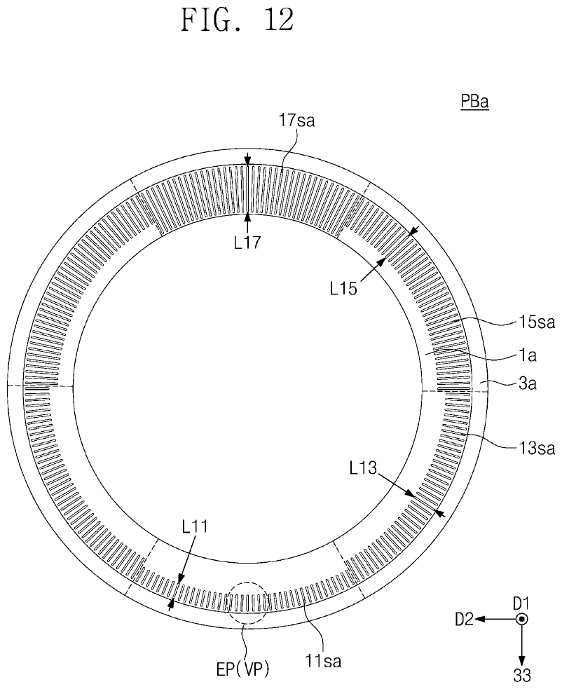

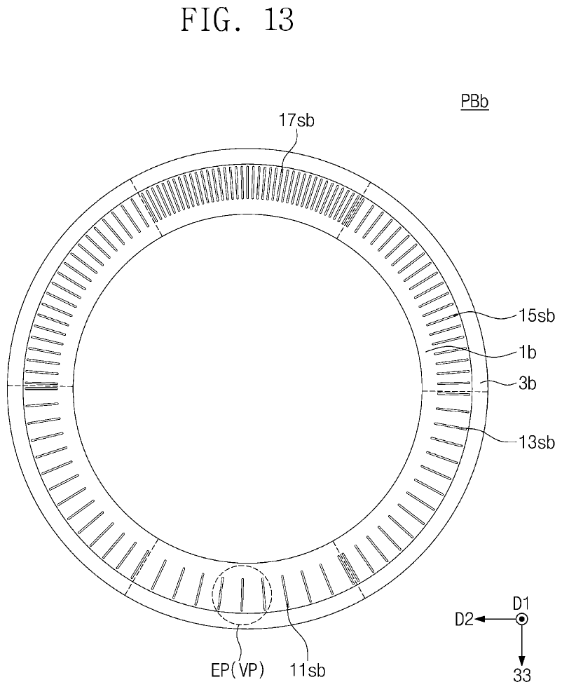

Referring to FIG. 6, a plurality of lower slits is may be spaced apart from each other in a circumferential direction. The plurality of lower slits 1s may be spaced apart at similar intervals from each other. In addition, the plurality of lower slits 1s may have similar lengths to each other. The present disclosure, however, is not limited thereto, and the plurality of lower slits 1s may be spaced apart at different intervals from each other. Alternatively, the plurality of lower slits 1s may have different lengths from each other. A detailed description thereof will be further discussed below with reference to FIGS. 12 and 13.

FIG. 7 is a flowchart of a substrate processing method according to an example embodiment.

Referring to FIG. 7, a substrate processing method S may be provided. The substrate processing method S may refer to a method in which a substrate undergoes a process using the substrate processing apparatus A discussed with reference to FIGS. 1 to 6.

The substrate processing method S may include an operation S1 of placing a substrate on a stage, an operation S2 of supplying a process gas into a process chamber, an operation S3 of exhausting a portion of the process gas from the process chamber, and an operation S4 of applying an RF power to generate plasma.

The process gas supply operation S2 may include may include an operation S21 of supplying a first process gas into the process chamber and an operation S22 of supplying a second process gas into the process chamber.

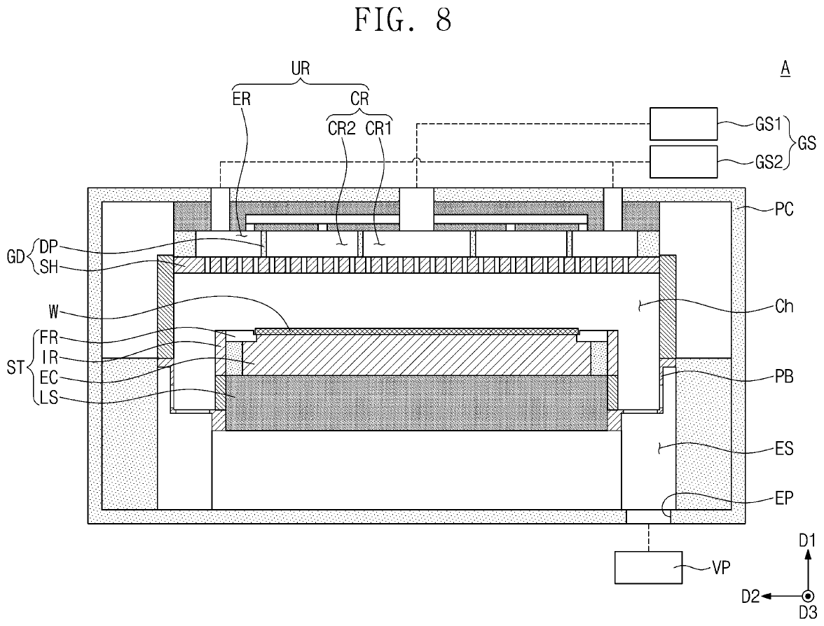

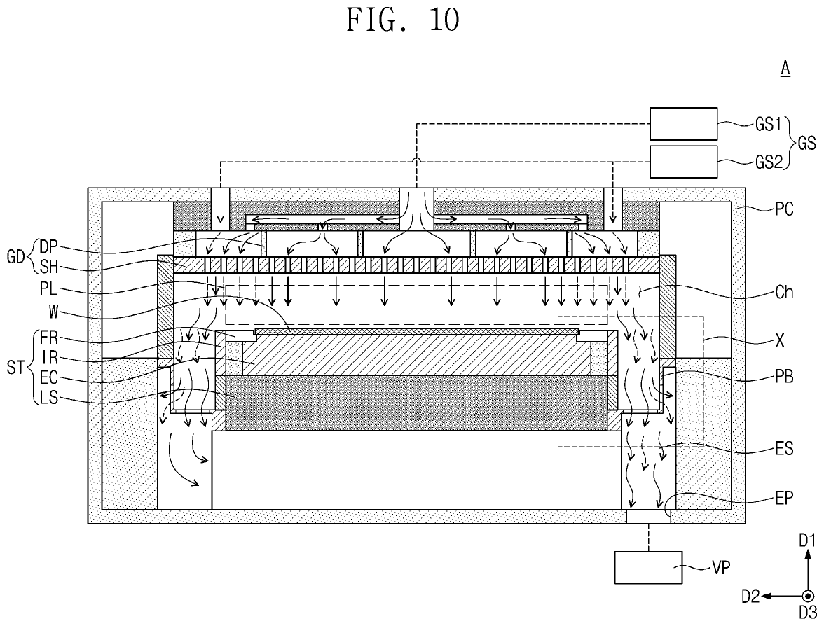

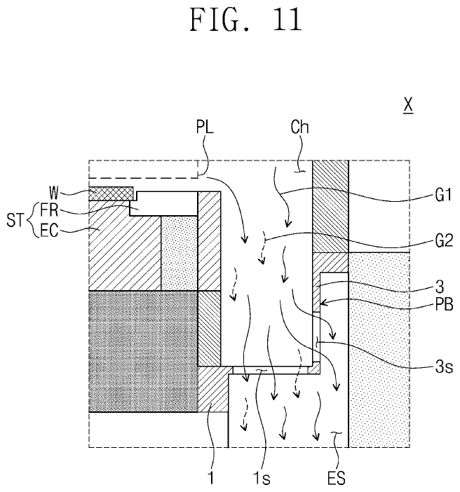

The substrate processing method S of FIG. 7 will be described in detail with reference to FIGS. 8 to 11.

FIGS. 8, 9, 10 and 11 are cross-sectional views of a substrate processing method according to the flowchart of FIG. 7, according to an example embodiment.

Referring to FIGS. 7 and 8, the substrate placement operation 51 may include a placing a substrate W on the electrostatic chuck EC. A robot arm may load the substrate W into the process chamber PC. The electrostatic chuck EC may cause the substrate W to rigidly rest on a certain position thereon.

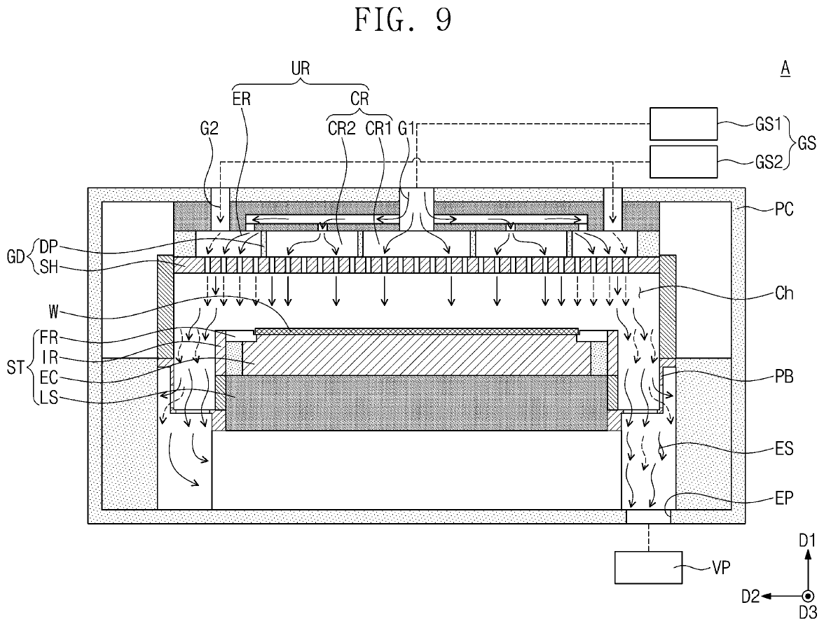

Referring to FIGS. 7 and 9, the first process gas supply operation S21 may include allowing the first gas supply unit GS1 to supply a first process gas G1. For example, the first process gas G1 may be supplied from the first gas supply unit GS1 through the distribution space UR and the showerhead SH to the process space Ch. In FIG. 9, a solid arrow may indicate a flow of the first process gas G1. The first process gas G1 may be relatively uniformly spread on the substrate W.

The second process gas supply operation S22 may include allowing the second gas supply unit GS2 to supply a second process gas G2. For example, the second process gas G2 may be supplied from the second gas supply unit GS2 through the edge region ER and the showerhead SH to the process space Ch. In FIG. 9, a dotted arrow may indicate a flow of the second process gas G2. The second process gas G2 may be supplied biased towards a space on an edge of the substrate W.

Referring to FIGS. 7, 10, and 11, the process gas exhaust operation S3 may include allowing the process chamber PC to outwardly discharge one or more of the first process gas G1 and the second process gas G2. One or more of the first process gas G1 and the second process gas G2 may move through the plasma baffle PB to the exhaust space ES. For example, one or more of the first process gas G1 and the second process gas G2 may pass through one or more of the lower slit is and the upper slit 3s. One or more of the first process gas G1 and the second process gas G2 may be outwardly discharged from the process chamber PC through the exhaust port EP. The vacuum pump VP may achieve the exhaustion mentioned above. For example, the vacuum pump VP may provide a vacuum pressure to move one or more of the first process gas G1 and the second process gas G2.

The plasma generation operation S4 may include providing a plasma electrode with a radio-frequency (RF) power to generate plasma PL from a portion one or more of the first process gas G1 and the second process gas G2. The plasma PL may not be allowed to easily pass through the plasma baffle PB. Therefore, the plasma PL may be concentrated on the substrate W. The substrate W may undergo a treatment process that uses the plasma PL. For example, the plasma PL may partially etch a top surface of the substrate W or may form a thin layer on the substrate W. At the time when the plasma PL is generated on the substrate W, one or more of the first process gas G1 and the second process gas G2 may be continuously supplied. In addition, at the time when the plasma PL is generated on the substrate W, one or more of the first process gas G1 and the second process gas G2 may be continuously exhausted.

According to a plasma baffle, a substrate processing apparatus including the same, and a substrate processing method using the same in accordance with some embodiments of the present disclosure, a slit may be provided on an upper ring. A process gas supplied during process may be exhausted not only through a lower slit but also through an upper slit. Therefore, the process gas may be satisfactorily discharged. Accordingly, it may be possible to control distribution of the process gas supplied onto a substrate. In addition, it may be possible to control distribution of plasma generated from the process gas. For example, the plasma distribution may be improved on an edge region of the substrate. As a result, the substrate may increase in process yield.

According to a plasma baffle, a substrate processing apparatus including the same, and a substrate processing method using the same in accordance with some embodiments of the present disclosure, the upper slit may be independently present spaced apart from the lower slit. Thus, irrespective of the lower slit, it may be possible to design a length, a width, and the number of the upper slit. There may be a diversification of parameters for controlling plasma distribution. In conclusion, the plasma distribution may be controlled in various ways.

In the embodiments that follow, omission will be made to avoid description of features substantially identical or similar to those discussed with reference to FIGS. 1 to 11.

FIG. 12 is a plan view of a plasma baffle according to an example embodiment.

Referring to FIG. 12, a plasma baffle PBa may include a lower ring 1a and an upper ring 3a. The lower ring 1a may provide a first lower slit 11sa, a second lower slit 13sa, a third lower slit 15sa, and a fourth lower slit 17sa.

A length of the first lower slit 11sa may be referred to as a first lower slit length L11. The first lower slit 11sa may be close to the exhaust port EP. For example, a distance between the first lower slit 11sa and the exhaust port EP may be less than that between the exhaust port EP and each of the second, third, and fourth lower slits 13sa, 15sa, and 17sa.

The second lower slit 13sa may be spaced apart in a circumferential direction from the first lower slit 11sa. A length of the second lower slit 13sa may be referred to as a second lower slit length L13. The second lower slit length L13 may be less than the first lower slit length L11. A distance between the second lower slit 13sa and the exhaust port EP may be less than that between the exhaust port EP and each of the third and fourth lower slits 15sa and 17sa.

The third lower slit 15sa may be spaced apart in a circumferential direction from the second lower slit 13sa. A length of the third lower slit 15sa may be referred to as a third lower slit length L15. The third lower slit length L15 may be less than the second lower slit length L13. A distance between the third lower slit 15sa and the exhaust port EP may be less than that between the exhaust port EP and the fourth lower slit 17sa.

The fourth lower slit 17sa may be spaced apart in a circumferential direction from the third lower slit 15sa. A length of the fourth lower slit 17sa may be referred to as a fourth lower slit length L17. The fourth lower slit length L17 may be less than the third lower slit length L15.

According to a plasma baffle, a substrate processing apparatus including the same, and a substrate processing method using the same in accordance with some embodiments of the present disclosure, there may be a difference in length between slits that are arranged in a circumferential direction. Therefore, it may be possible to control distribution of process gas and/or plasma. A slit nearby an exhaust port may have a relatively small length. For example, a relatively small length may be provided to a slit positioned at a location on which a vacuum pump has a great effect. Thus, at a position where the vacuum pump greatly affects, the process gas may be prevented from being excessively exhausted through the slit. Accordingly, it may be possible to control distribution of process gas and/or plasma.

FIG. 13 is a plan view of a plasma baffle according to an example embodiment.

Referring to FIG. 13, a plasma baffle PBb may include a lower ring 1b and an upper ring 3b. The lower ring 1b may provide a first lower slit 11sb, a second lower slit 13sb, a third lower slit 15sb, and a fourth lower slit 17sb.

The first lower slit 11sb may be provided in plural. The plurality of first lower slits 11sb may be disposed spaced apart from each other in a circumferential direction. There may be a relatively large interval between the plurality of first lower slits 11sb.

The second lower slit 13sb may be provided in plural. The plurality of second lower slits 13sb may be disposed spaced apart from each other in a circumferential direction. An interval between the plurality of second lower slits 13sb may be less than that between the plurality of first lower slits 11sb.

The third lower slit 15sb may be provided in plural. The plurality of third lower slits 15sb may be disposed spaced apart from each other in a circumferential direction. An interval between the plurality of third lower slits 15sb may be less than that between the plurality of second lower slits 13sb.

The fourth lower slit 17sb may be provided in plural. The plurality of fourth lower slits 17sb may be disposed spaced apart from each other in a circumferential direction. An interval between the plurality of fourth lower slits 17sb may be less than that between the plurality of third lower slits 15sb.

FIG. 14 is an enlarged cutaway perspective view of a plasma baffle according to an example embodiment.

Referring to FIG. 14, a plasma baffle PBc may include a lower ring 1c and an upper ring 3c. The lower ring 1c may provide a lower slit 1sc. The upper ring 3c may provide an upper slit 3sc.

The lower slit 1sc may include a plurality of lower slits. The plurality of lower slits 1sc may have their similar lengths to each other.

The upper slit 3sc may include a first upper slit 31sc and a second upper slit 33sc. A length of the first upper slit 31sc may be referred to as a first upper slit length L31. A length of the second upper slit 33sc may be referred to as a second upper slit length L33. The second upper slit length L33 may be different from the first upper slit length L31. For example, the second upper slit length L33 may be less than the first upper slit length L31.

According to a plasma baffle, a substrate processing apparatus including the same, and a substrate processing method using the same in accordance with some embodiments of the present disclosure, a plurality of upper slits may have their different lengths from each other. The upper slits may be designed to have different lengths, and thus it may be possible to control plasma distribution in a circumferential direction.

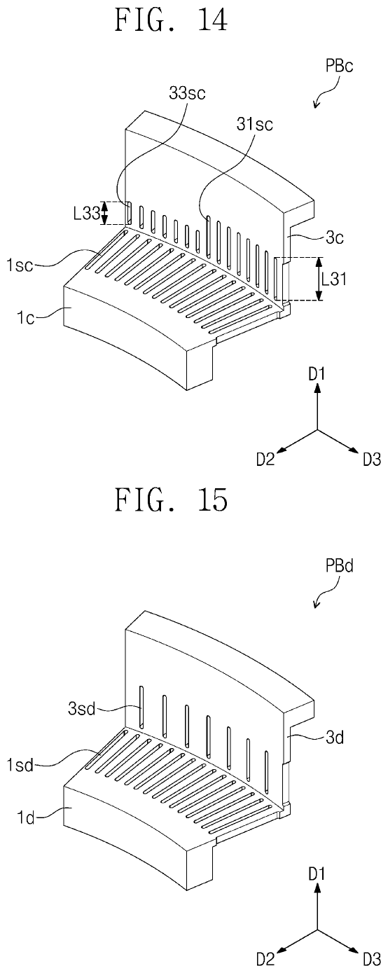

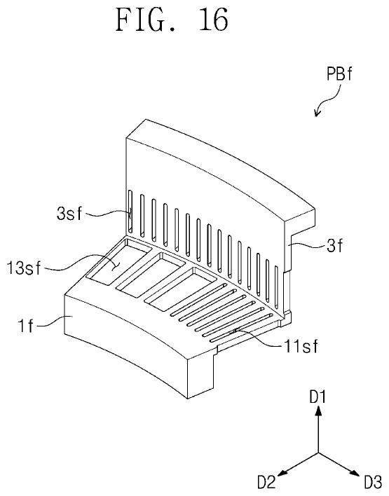

FIG. 15 is an enlarged cutaway perspective view partially of a plasma baffle according to an example embodiment.

Referring to FIG. 15, a plasma baffle PBd may include a lower ring 1d and an upper ring 3d. The lower ring 1d may provide a lower slit 1sd. The upper ring 3d may provide an upper slit 3sd.

The lower slit 1sd may be provided in plural. The upper slit 3sd may include a plurality of upper slits. The number of the lower slit 1sd may be different from that of the upper slit 3sd. For example, as illustrated in FIG. 15, the number of the lower slit 1sd may be greater than that of the upper slit 3sd. The present disclosure, however, is not limited thereto, and the number of the lower slit 1sd may be less than that of the upper slit 3sd.

According to a plasma baffle, a substrate processing apparatus including the same, and a substrate processing method using the same in accordance with some embodiments of the present disclosure, an upper slit may be provided as an aperture independently present separated from a lower slit. The number of the upper slit may be designed to be different from that of the lower slit. Accordingly, there may be a diversification of parameters for controlling plasma distribution.

FIG. 16 is an enlarged cutaway perspective view partially of a plasma baffle according to an example embodiment.

Referring to FIG. 16, a plasma baffle PBf may include a lower ring 1f and an upper ring 3f. The lower ring 1f may provide a lower slit 1sf. The upper ring 3f may provide an upper slit 3sf.

The lower slit 1sf may include a first lower slit 11sf and a second lower slit 13sf. The first lower slit 11sf and the second lower slit 13sf may be different in terms of width. For example, the width of the first lower slit 11sf may be less than that of the second lower slit 13sf. The upper slit 3sf may have a width similar to that of the first lower slit 11sf. The width of the upper slit 3sf may be different from that of the second lower slit 13sf.

According to a plasma baffle, a substrate processing apparatus including the same, and a substrate processing method using the same in accordance with some embodiments of the present disclosure, an upper slit may be provided as an aperture independently present separated from a lower slit. The number of the upper slit may be designed to be different from that of the lower slit. Accordingly, there may be a diversification of parameters for controlling plasma distribution.

According to a plasma baffle, a substrate processing apparatus including the same, and a substrate processing method using the same in accordance with the present disclosure, it may be possible to control plasma distribution on an edge region of a substrate.

According to a plasma baffle, a substrate processing apparatus including the same, and a substrate processing method using the same in accordance with the present disclosure, it may be possible to diversify parameters to control plasma distribution in various ways.

According to a plasma baffle, a substrate processing apparatus including the same, and a substrate processing method using the same in accordance with the present disclosure, it may be possible to control plasma distribution in a circumferential direction.

Effects of the present disclosure are not limited to the mentioned above, other effects which have not been mentioned above will be clearly understood to those skilled in the art from the following description.

Although the disclosure been described in connection with some embodiments illustrated in the accompanying drawings, it will be understood by one of ordinary skill in the art that variations in form and detail may be made therein without departing from the spirit and essential feature of the disclosure. The above disclosed embodiments should thus be considered illustrative and not restrictive.

What is claimed is:

1. A plasma baffle comprising:
a lower ring; and
an upper ring that extends upwardly from an edge of the lower ring,
wherein the lower ring comprises:
a lower central hole on a center of the lower ring and vertically penetrating the lower ring; and
a lower slit outside the lower central hole and vertically penetrating the lower ring, and
wherein the upper ring comprises:
an upper central hole on a center of the upper ring and vertically penetrating the upper ring; and
an upper slit that penetrates the upper ring to connect an inner lateral surface of the upper ring to an outer lateral surface of the upper ring.

2. The plasma baffle of claim 1, wherein the upper slit is spaced apart from the lower slit.

3. The plasma baffle of claim 1, wherein the lower slit comprises:
a first lower slit; and
a second lower slit spaced apart in a circumferential direction from the first lower slit, and
wherein a first length of the first lower slit in a radial direction of the first lower slit is different from a second length of the second lower slit in a radial direction of the second lower slit.

4. The plasma baffle of claim 1, wherein the upper slit comprises:
a first upper slit; and
a second upper slit spaced apart in a circumferential direction from the first upper slit, and
wherein a first length of the first upper slit in an extending direction of the upper ring is different from a second length of the second upper slit in the extending direction of the upper ring.

5. The plasma baffle of claim 1, wherein a width of the upper slit is different from a width of the lower slit.

6. The plasma baffle of claim 5, wherein the width of the upper slit is less than the width of the lower slit.

7. The plasma baffle of claim 1, wherein the lower ring comprises:
a plurality of lower slits including the lower slit, the plurality of lower slits being spaced apart from each other in a circumferential direction,
a plurality of upper slits including the upper slit, the plurality of upper slits being spaced apart from each other in the circumferential direction, and
wherein a number of the plurality of lower slits is different from a number of the plurality of upper slits.

8. The plasma baffle of claim 1, wherein a length of the upper slit in an extending direction of the upper ring is less than a length of the lower slit in the extending direction of the upper ring.

9. The plasma baffle of claim 1, wherein a length of the lower slit in a radial direction is in a range from about 70 mm to about 100 mm, and
wherein a length of the upper slit in an extending direction of the upper ring is in a range of about 30 mm to about 50 mm.

10. A substrate processing apparatus comprising:
a stage configured to support a substrate; and
a plasma baffle that surrounds the stage,
wherein the plasma baffle comprises a lower ring,
wherein the lower ring comprises a lower central hole and a lower slit that extends in a radial direction of the lower ring and vertically penetrates the lower ring,
wherein the lower slit comprises:
a first lower slit; and
a second lower slit spaced apart in a circumferential direction from the first lower slit, and
wherein a first length of the first lower slit in the radial direction is different from a second length of the second lower slit in the radial direction.

11. The substrate processing apparatus of claim 10, further comprising:
a process chamber in which the stage and the plasma baffle are disposed; and
a vacuum pump,
wherein the process chamber comprises an exhaust port, and
wherein the vacuum pump is connected through the exhaust port to a process space of the process chamber.

12. The substrate processing apparatus of claim 11, wherein the first length of the first lower slit is less than the second length of the second lower slit, and
wherein a distance between the first lower slit and the exhaust port is less than a distance between the second lower slit and the exhaust port.

13. The substrate processing apparatus of claim 11, further comprising:
a first gas supply unit configured to supply a first process gas to the process space; and
a second gas supply unit configured to supply a second process gas to the process space.

14. The substrate processing apparatus of claim 13, further comprising a gas distribution unit configured to distribute the first process gas and the second process gas over the process space,
wherein the gas distribution unit comprises:
a showerhead; and
a gas separation plate provided on the showerhead,
wherein the gas separation plate divides a space above the showerhead into a central region and an edge region, and
wherein the second gas supply unit is connected to the edge region and configured to deliver the second process gas to the edge region.

15. The substrate processing apparatus of claim 10, wherein the plasma baffle further comprising an upper ring that extends upwardly from an edge of the lower ring, and
wherein the upper ring comprises an upper slit that penetrates the upper ring to connect an inner lateral surface of the upper ring to an outer lateral surface of the upper ring.

16. The substrate processing apparatus of claim 15, wherein the upper slit comprises:
a first upper slit; and
a second upper slit spaced apart in a circumferential direction from the first upper slit, and
wherein a first length of the first upper slit in an extending direction of the upper ring is different from a second length of the second upper slit in the extending direction of the upper ring.

17. The substrate processing apparatus of claim 15, wherein a width of the upper slit is different from a width of the lower slit.

18. A substrate processing method comprising:
providing a substrate on a stage of a substrate processing apparatus;
supplying a process gas to a process chamber of the substrate processing apparatus;
exhausting a portion of the process gas from the process chamber; and
applying a radio-frequency (RF) power to generate plasma on the substrate,
wherein the substrate processing apparatus comprises a plasma baffle that surrounds the stage,
wherein the plasma baffle comprises:
a lower ring; and
an upper ring that extends upwardly from an edge of the lower ring,
wherein the lower ring comprises a lower slit that extends in a radial direction of the lower ring and vertically penetrates the lower ring,
wherein the upper ring comprises an upper slit that penetrates the upper ring to connect an inner lateral surface of the upper ring to an outer lateral surface of the upper ring, and
wherein exhausting the portion of the process gas from the process chamber comprises passing the portion of the process gas through the upper slit.

19. The substrate processing method of claim 18, wherein supplying the process gas to the process chamber comprises:
supplying, by a first gas supply unit, a first process gas into the process chamber; and
supplying, by a second gas supply unit, a second process gas into the process chamber, the second process gas being different from the first process gas.

20. The substrate processing method of claim 18, wherein the upper slit comprises:
a first upper slit; and
a second upper slit spaced apart in a circumferential direction from the first upper slit, and
wherein a first length of the first upper slit in an extending direction of the upper ring is different from a second length of the second upper slit in the extending direction of the upper ring.
